(19) United States
(12) Patent Application Publication
(10) Pub. No.: US 2024/0395658 A1
(43) Pub. Date: Nov. 28, 2024

(54) SEMICONDUCTOR DEVICE AND MANUFACTURING METHOD OF SEMICONDUCTOR DEVICE

(71) Applicant: Kioxia Corporation, Tokyo (JP)

(72) Inventor: Masashi WAKISAKA, Yokohama Kanagawa (JP)

(73) Assignee: Kioxia Corporation, Tokyo (JP)

(21) Appl. No.: 18/668,478

(22) Filed: May 20, 2024

(30) Foreign Application Priority Data
May 23, 2023 (JP) 2023-084551

(51) Int. Cl. H01L 23/373; H01L 23/00

(52) U.S. Cl. CPC H01L 23/373; H01L 24/16; H01L 24/29; H01L 24/32; H01L 24/73; H01L 24/92; H01L 2224/16225; H01L 2224/29193; H01L 2224/32225; H01L 2224/73203; H01L 2224/9211

(57) ABSTRACT

A semiconductor device includes a semiconductor package including a first surface with a first region and a second region around the first region, wherein the first region includes a first solder ball; and a heat conductive body in contact with the second region, wherein the heat conductive body includes graphite and has a thermal conductivity equal to or higher than 400 W/m·K in a use temperature range.

### CROSS-REFERENCE TO RELATED APPLICATION

This application is based upon and claims the benefit of priority from Japanese Patent Application No. 2023-084551, filed May 23, 2023, the entire contents of which are incorporated herein by reference.

### FIELD

Embodiments described herein relate generally to a semiconductor device and a manufacturing method of a semiconductor device.

### BACKGROUND

In recent years, a memory system including a memory and a controller on a wiring board is known. In such a memory system, electronic components such as a memory and a controller are mounted on a wiring board via a connection member such as a solder ball.

### DESCRIPTION OF THE DRAWINGS

FIG. 1 is a block diagram showing a configuration example of a memory system.

FIG. 2 is a schematic diagram showing a first structural example of a memory system.

FIG. 3 is a schematic diagram showing a first structural example of a memory system.

FIG. 4 is a schematic diagram showing a first structural example of a memory system.

FIG. 5 is a schematic diagram showing a manufacturing method example of the first structural example.

FIG. 6 is a schematic diagram showing a manufacturing method example of the first structural example.

FIG. 7 is a schematic diagram showing a second structural example of a memory system.

FIG. 8 is a schematic diagram showing a second structural example of a memory system.

FIG. 9 is a schematic diagram showing a second structural example of a memory system.

FIG. 10 is a schematic diagram showing a third structural example of a memory system.

FIG. 11 is a schematic diagram showing a third structural example of a memory system.

FIG. 12 is a schematic diagram showing a third structural example of a memory system.

FIG. 13 is a schematic diagram showing a configuration example of a semiconductor module having a memory system.

FIG. 14 is a schematic diagram showing a configuration example of a semiconductor module having a memory system.

FIG. 15 is a schematic diagram showing a configuration example of a vehicle having a semiconductor module.

### DETAILED DESCRIPTION

Embodiments provide a semiconductor device with a high heat dissipation.

In general, according to one embodiment, there is provided a semiconductor device including a semiconductor package including a first surface with a first region and a second region around the first region, wherein the first region includes a first solder ball; and a heat conductive body in contact with the second region, wherein the heat conductive body includes graphite and has a thermal conductivity equal to or higher than 400 W/m·K in a use temperature range.

Hereinafter, embodiments will be described with reference to the drawings. The relationship between the thickness and the plane dimensions of each element shown in the drawings, the ratio of the thicknesses of each element, and the like may differ from the actual relationship, ratio, and the like. In addition, in the embodiment, the same reference numerals are given to substantially the same elements, and the description thereof will be omitted or simplified as appropriate.

In the present embodiment, the term “connected” includes not only physical connection but also electrical connection, unless otherwise specified.

### Embodiment of Semiconductor Device

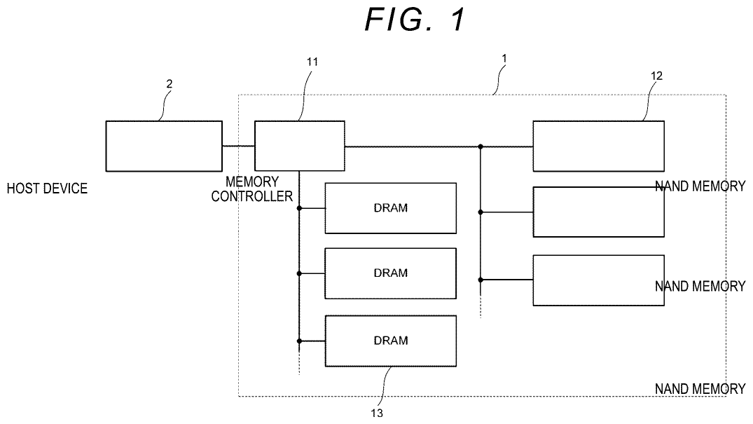

FIG. 1 is a block diagram showing a configuration example of a memory system which is an example of a semiconductor device. The memory system 1 is configured to be connected to the host device 2.

The memory system 1 includes a storage device such as a solid state drive (SSD). The storage device can be used for various electronic devices such as personal computers, smartphones, and tablets, and vehicles such as automobiles.

The host device 2 has a function of controlling the memory system 1. Examples of the host device 2 include a server, a personal computer, a central processing unit (CPU), and the like.

The memory system 1 includes a memory controller 11, a NAND memory 12, and a dynamic random access memory (DRAM) 13. The memory system 1 can be formed by connecting electronic components such as the memory controller 11, the NAND memory 12, and the DRAM 13 to a wiring board.

The memory controller 11 controls the execution of operations such as writing, reading, and erasing of data with respect to the NAND memory 12 and the DRAM 13 based on, for example, an access request from the host device 2. The memory controller 11 is an example of an electronic component. The memory controller 11 is a semiconductor device configured as, for example, an SoC.

The NAND memory 12 is a NAND-type flash memory. The NAND memory 12 stores data in a non-volatile manner. Although FIG. 1 shows three NAND memories 12, the number of the NAND memories 12 is not limited to three. The NAND memory 12 is an example of an electronic component.

The DRAM 13 temporarily stores, for example, data received from the host device 2 and to be written into the NAND memory 12, data read from the NAND memory 12 and to be transmitted to the host device 2, and the like. Although FIG. 1 shows three DRAMs 13, the number of the DRAMs 13 is not limited to three. The DRAM 13 is an example of an electronic component.

### First Structural Example of Memory System 1

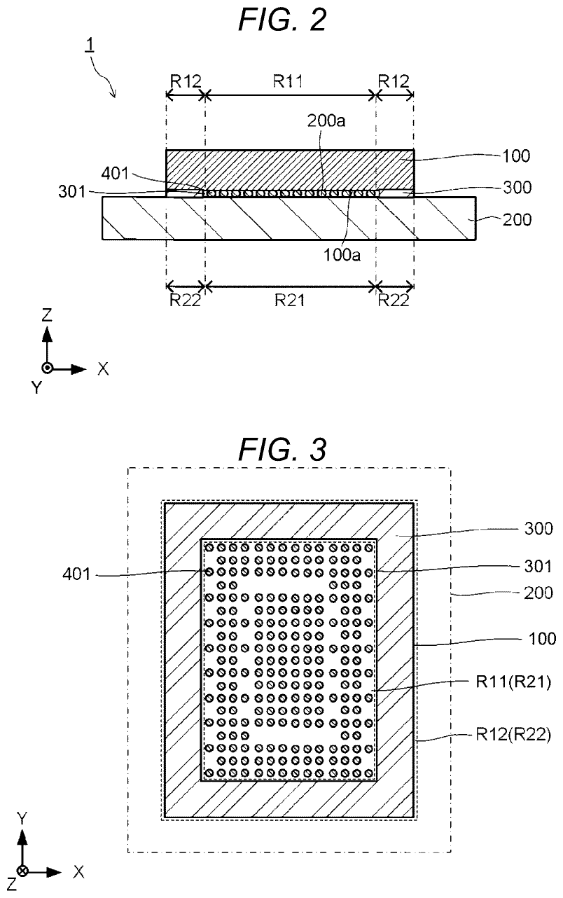

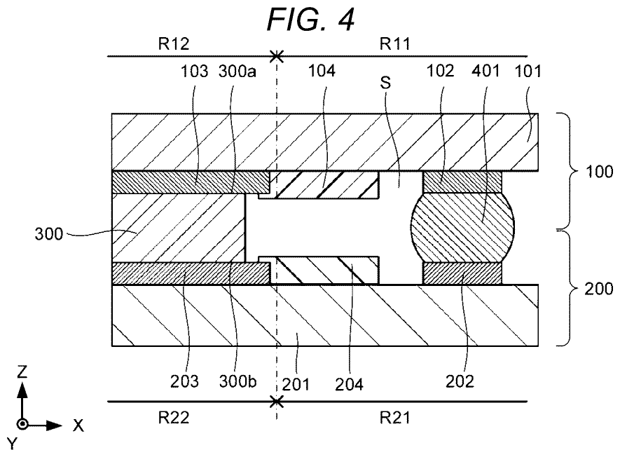

FIGS. 2, 3, and 4 are schematic diagrams showing a first structural example of the memory system 1. FIGS. 2, 3, and 4 show an X axis along a first direction, a Y axis along a second direction perpendicular to the X axis, and a Z axis along a third direction perpendicular to each of the X axis and the Y axis. FIG. 2 shows a part of an X-Z cross section of the memory system 1. FIG. 3 shows a part of the X-Y plane of the memory system 1. FIG. 4 is an enlarged diagram of a part of the X-Z cross section of the memory system 1 shown in FIG. 2.

A first structural example of the memory system 1 has a semiconductor package 100, a wiring board 200, and a heat conductive body 300. FIG. 3 shows a part of the X-Y plane when the memory system 1 is viewed from the wiring board 200 side, and for convenience, the wiring board 200 is shown by a one-dot chain line. The Z axis is the same direction as a thickness direction of the semiconductor package 100 and a thickness direction of the wiring board 200.

The semiconductor package 100 is, for example, a ball grid array (BGA) package. The semiconductor package 100 may have, for example, a memory controller 11, a NAND memory 12, and a DRAM 13, as shown in FIG. 1. In addition, in the first structural example of the memory system 1, a plurality of semiconductor packages 100 may be provided, and each of the plurality of semiconductor packages 100 may have the memory controller 11, the NAND memory 12, and the DRAM 13.

The semiconductor package 100 has a surface 100a. The surface 100a is an exposed surface of the semiconductor package 100. As shown in FIGS. 2 and 3, the surface 100a has a region R11 and a region R12. The region R11 is provided inside the region R12 in the X-Y plane. The region R11 is, for example, surrounded by the region R12 in the X-Y plane. The region R12 is provided outside the region R11. The region R12 is, for example, in the X-Y plane, provided around the region R11 and surrounds the region R11. A large number of communication lines that communicate with the outside of the semiconductor package 100 are disposed in the region R11. The outside is, for example, the host device 2. The region R11 has higher heat generation property than the region R12. That is, the amount of heat generated per unit time in the region R11 is larger than the amount of heat generated per unit time in the region R12.

The first structural example of the semiconductor package 100 will be further described with reference to FIG. 4. As shown in FIG. 4, the semiconductor package 100 includes an internal layer 101, a conductive pad 102, a conductive pad 103, and an insulating layer 104.

The internal layer 101 is a stacked layer in which an insulating layer and a wiring layer are alternately stacked. Examples of the insulating layer include insulators such as a glass cloth, a glass substrate, a ceramic substrate, a glass epoxy substrate, and a prepreg, and insulating resin layers such as a solder resist layer. The wiring layer can be formed using a metal material, for example, such as copper. The internal layer 101 may have a plurality of insulating layers and a plurality of wiring layers.

The conductive pad 102 is provided on the surface of the insulating layer of the internal layer 101 in the region R11. The conductive pad 102 is, for example, electrically connected to one of the wiring layers of the internal layer 101, and is electrically connected to an electronic component such as the memory controller 11, the NAND memory 12, and the DRAM 13 provided in the semiconductor package 100 through the wiring layer.

The conductive pad 103 is provided on the surface of the insulating layer of the internal layer 101 in the region R12. The conductive pad 103 is, for example, electrically connected to another one of the wiring layers of the internal layer 101, and is connected to a wiring that supplies a ground voltage through the wiring layer.

The conductive pad 102 and the conductive pad 103 are exposed from the insulating layer 104. The semiconductor package 100 has a plurality of conductive pads 102 and a plurality of conductive pads 103. The conductive pad 102 and the conductive pad 103 can be exposed from the insulating layer 104 by, for example, forming the insulating layer 104 on the internal layer 101 to cover the conductive pad 102 and the conductive pad 103, and then partially etching the insulating layer 104.

The insulating layer 104 is provided on the surface of the internal layer 101. The insulating layer 104 may be in contact with a part of the surfaces of the conductive pad 102 and the conductive pad 103. Examples of the insulating layer 104 include a solder resist layer.

Examples of the wiring board 200 include a printed wiring board (PWB) and the like. As shown in FIGS. 2 and 3, the wiring board 200 has a surface 200a. The surface 200a is an exposed surface of the wiring board 200. The surface 200a has a region R21 and a region R22. The region R21 is provided inside the region R22 in the X-Y plane. The region R21 is, for example, surrounded by the region R22 in the X-Y plane. The region R22 is provided outside the region R21 in the X-Y plane. The region R22 is, for example, in the X-Y plane, provided around the region R21 and surrounds the region R21.

The structural example of the wiring board 200 will be further described with reference to FIG. 4. The wiring board 200 has an internal layer 201, a conductive pad 202, a conductive pad 203, and an insulating layer 204.

The internal layer 201 is a stacked layer in which an insulating layer and a wiring layer are alternately stacked. Examples of the insulating layer include insulators such as a glass cloth, a glass substrate, a ceramic substrate, a glass epoxy substrate, and a prepreg, and insulating resin layers such as a solder resist layer. The wiring layer can be formed using a metal material, for example, such as copper.

The conductive pad 202 is provided on the surface of the insulating layer of the internal layer 201 in the region R21. The conductive pad 202 is, for example, electrically connected to the wiring layer of the internal layer 201, and is connected to a terminal for supplying a power supply voltage or an electrical signal through the wiring layer.

The conductive pad 203 is provided on the surface of the insulating layer of the internal layer 201 in the region R22. The conductive pad 203 is, for example, electrically connected to another one of the wiring layers of the internal layer 201 and is connected to a terminal for supplying a ground voltage through the wiring layer.

The conductive pad 202 and the conductive pad 203 are exposed from the insulating layer 204. The wiring board 200 has a plurality of conductive pads 202 and a plurality of conductive pads 203. The conductive pad 202 and the conductive pad 203 can be exposed from the insulating layer 204 by, for example, forming the insulating layer 204 on the internal layer 201 to cover the conductive pad 202 and the conductive pad 203, and then partially etching the insulating layer 204.

The insulating layer 204 is provided on the surface of the internal layer 201. The insulating layer 204 may be in contact with a part of the surfaces of the conductive pad 202 and the conductive pad 203. Examples of the insulating layer 204 include a solder resist layer. The memory system 1 has a solder ball 401 that connects the conductive pad 102 and the conductive pad 202. As shown in FIGS. 2 and 3, the solder ball 401 is disposed in the region R11, for example, and is provided on the surface of the conductive pad 102. The solder ball 401 may have a circular shape, for example, in the X-Y plane. The maximum diameter of the solder ball 401 in the Z-axis direction is, for example, 100 μm or more and 300 μm or less. The maximum diameter of the solder ball 401 in the X-axis direction or the Y-axis direction is 300 μm or more and 550 μm or less. The memory system 1 includes a plurality of solder balls 401. The solder ball 401 can be formed using, for example, tin-silver-based or tin-silver-copper-based lead-free solder. The semiconductor package 100 and the wiring board 200 are bonded by the solder ball 401.

When the memory system 1 has a space S between the surface 100a and the surface 200a, the space S may be filled with a resin material such as an underfill resin. The space S extends between, for example, the plurality of solder balls 401.

The heat conductive body 300 is provided between the region R12 and the region R22 and is in contact with each of the region R12 and the region R22. In other words, the heat conductive body 300 is provided between the semiconductor package 100 and the wiring board 200, and is in contact with each of the semiconductor package 100 and the wiring board 200. The heat conductive body 300 has a surface 300a that is in contact with the conductive pad 103 and a surface 300b that is in contact with the conductive pad 203. A shape of the heat conductive body 300 is not particularly limited, but is, for example, a rectangular shape having an opening 301 in the X-Y plane. The opening 301 overlaps with the region R11 when viewed in the Z-axis direction and penetrates the heat conductive body 300 in the Z-axis direction. Therefore, the heat conductive body 300 does not overlap with the region R11 and is not in contact with the region R11 when the heat conductive body 300 is viewed in the thickness direction (Z-axis direction) of the wiring board 200. The solder ball 401 is disposed, for example, inside the opening 301, and connects the conductive pad 102 and the conductive pad 202 each other in the opening 301.

The heat conductive body 300 includes graphite. The heat conductive body 300 has a thermal conductivity of 400 W/m·K or more in the use temperature range of the memory system 1. The use temperature range is, for example, −40° C. or higher and 105° C. or lower. The upper limit of the thermal conductivity is, for example, 1000 W/m·K or less. The thickness of the heat conductive body 300 is, for example, smaller than the maximum diameter of the solder ball 401 in the Z-axis direction. The thickness of the heat conductive body 300 is, for example, 70 μm or more and 100 μm or less. In the above-mentioned use temperature range, an electrical conductivity of the heat conductive body 300 is, for example, 1×105 S/m or more and 5×106 S/m or less.

Examples of the heat conductive body 300 include Graphite Thermal Interface Material (Graphite TIM (registered trademark)). The Graphite TIM is a graphite sheet having multilayer graphene including a plurality of graphene layers stacked in the Z-axis direction. Each graphene layer has a two-dimensional structure formed of a carbon six-membered ring along the X-Y plane. The Graphite TIM has a thermal conductivity of 400 W/m·K or more and 1000 W/m·K or less, which is higher than, for example, the thermal conductivity of the underfill resin or the thermal conductivity of the silicone-based TIM in the above-described use temperature range.

When the semiconductor package 100 and the wiring board 200 are connected by the plurality of solder balls 401, the contact between the semiconductor package 100 and the wiring board 200 is point contact in the X-Y plane. As a result, since the air layer is present between the semiconductor package 100 and the wiring board 200, a large thermal resistance is formed, and heat is less likely to be dissipated from the semiconductor package 100 to the wiring board 200.

In the present structural example, in the X-Y plane, the total area of a region where the heat conductive body 300 is in contact with the surface 100a and the surface 200a is easily increased compared to the total area of a region where the plurality of solder balls 401 are in contact with the surface 100a and the surface 200a. In other words, by providing the heat conductive body 300 between the semiconductor package 100 and the wiring board 200, the total contact area between the semiconductor package 100 and the wiring board 200 by the heat conductive body 300 can be increased compared to the total contact area between the semiconductor package 100 and the wiring board 200 by the plurality of solder balls 401. For example, in the X-Y plane, the area of the heat conductive body 300 can be 25 times or more the total area of the plurality of solder balls 401.

The heat conductive body 300 has a higher thermal conductivity than the thermal conductivity of the air layer. By filling the air layer between the semiconductor package 100 and the wiring board 200 with the heat conductive body 300, heat can be easily dissipated from the semiconductor package 100 to the wiring board 200.

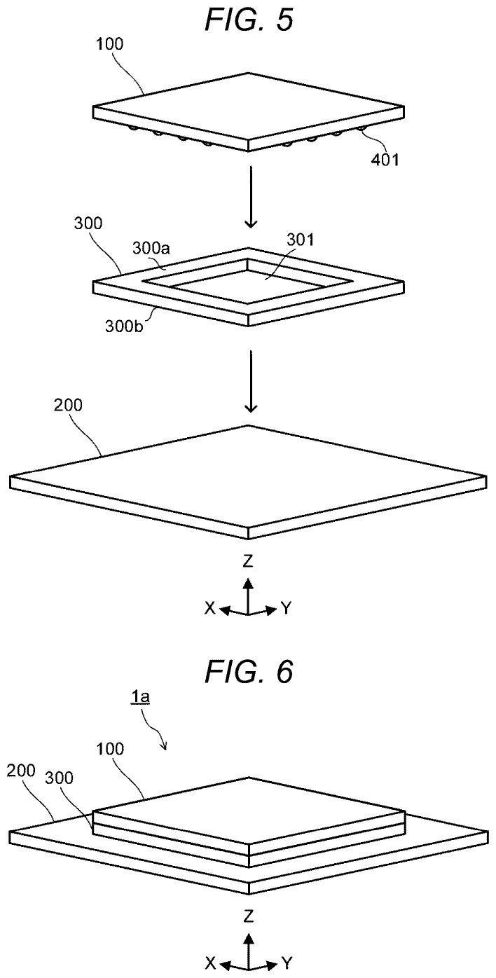

Next, a manufacturing method example of the first structural example of the memory system 1 will be shown with reference to FIGS. 5 and 6. FIGS. 5 and 6 are schematic diagrams showing a manufacturing method example of the first structural example. FIGS. 5 and 6 are perspective diagrams of the memory system 1.

In the manufacturing method example of the first structural example, as shown in FIG. 5, the semiconductor package 100, the wiring board 200, and the heat conductive body 300 are prepared. The semiconductor package 100, the wiring board 200, and the heat conductive body 300 are disposed to overlap in the Z-axis direction.

Next, the semiconductor package 100 and the wiring board 200 are stacked with the heat conductive body 300 sandwiched therebetween to form a stacked body 1a as shown in FIG. 6. At this time, as shown in FIGS. 2 to 4, the heat conductive body 300 is disposed to be in contact with each of the conductive pad 103 of the surface 100a and the conductive pad 203 of the surface 200a, and is fixed between the semiconductor package 100 and the wiring board 200. In addition, as shown in FIG. 4, the solder ball 401 is disposed to be in contact with each of the conductive pad 102 of the surface 100a and the conductive pad 202 of the surface 200a. Thereafter, the stacked body 1a shown in FIG. 6 is heated to reflow the solder balls 401 and melt the solder balls 401, thereby bonding the semiconductor package 100 and the wiring board 200. After the reflow, the gap between the semiconductor package 100 and the wiring board 200 is sufficiently narrow to sandwich and fix the heat conductive body 300 therebetween. The gap is, for example, 160 μm. The memory system 1 can be manufactured by the above steps.

As described above, in the first structural example of the memory system 1, by providing the heat conductive body 300 between the semiconductor package 100 and the wiring board 200, the heat dissipation area than the total area of the plurality of solder balls 401 can be increased in the X-Y plane. Therefore, the heat dissipation of the memory system 1 can be improved.

In addition, the above-described structural example shows an example in which a solder ball is used to bond the semiconductor package 100 and the wiring board 200. At this time, the heat conductive body 300 is fixed by being sandwiched between the semiconductor package 100 and the wiring board 200. However, when the semiconductor package 100 and the wiring board 200 are bonded by a method other than the method of using the solder ball, for example, the heat conductive body 300 may be fixed between the semiconductor package 100 and the wiring board 200 using an adhesive such as an underfill, a corner fill, or a corner bond.

### Second Structural Example of Memory System 1

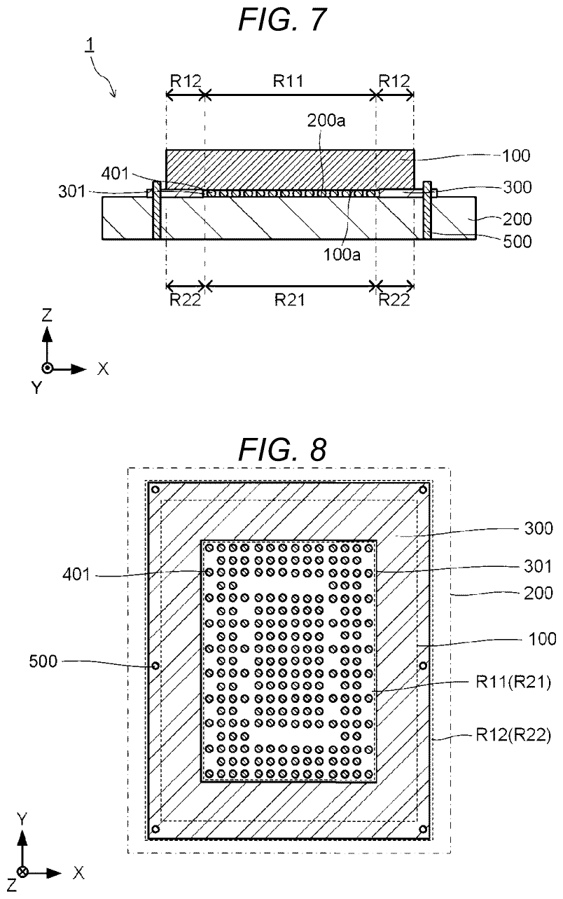

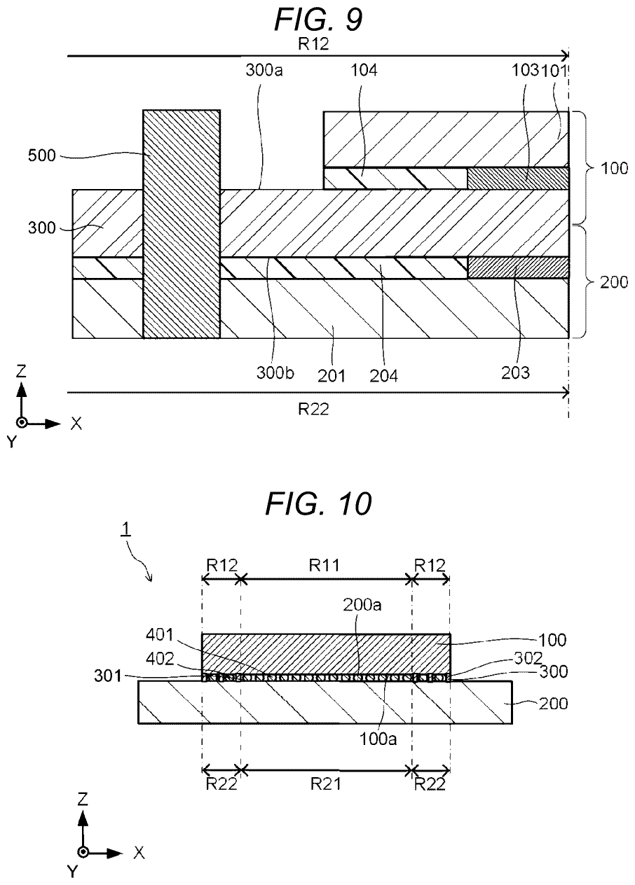

The structural example of the memory system 1 is not limited to the first structural example. FIGS. 7, 8, and 9 are schematic diagrams showing a second structural example of the memory system 1. FIG. 7 shows a part of the X-Z cross section of the memory system 1. FIG. 8 shows a part of the X-Y plane of the memory system 1. FIG. 9 is an enlarged diagram of a part of the X-Z cross section of the memory system 1 shown in FIG. 7.

The second structural example is different from the first structural example in that the heat conductive body 300 extends to protrude from the semiconductor package 100 in the X-Y plane, and the heat conductive body 300 is fixed to the wiring board 200 by the screw 500. In the following, a part of the second structural example different from the first structural example will be described. For the same parts as in the first structural example, the description of the first structural example can be appropriately incorporated.

The heat conductive body 300 extends to protrude outward the semiconductor package 100 in the X-Y plane. The heat conductive body 300 is fixed to the wiring board 200 by a protruding portion of the heat conductive body 300 and the screw 500 penetrating the wiring board 200 in the Z-axis direction.

In the regions R12 and R22, the screw 500 penetrates the internal layer 201 and the insulating layer 204 in the Z-axis direction. The screw 500 includes, for example, metal. The second structural example includes a plurality of screws 500. The plurality of screws 500 are provided, for example, in a portion that does not overlap with the semiconductor package 100 in the Z-axis direction along the periphery of the heat conductive body 300 in the X-Y plane. The number of screws 500 is not limited to six shown in FIG. 8.

As described above, in the second structural example, the total area of the region where the heat conductive body 300 is in contact with each of the surface 100a and the surface 200a can be easily increased in the X-Y plane compared to the total area of the region in the first structural example. In other words, the total contact area between the semiconductor package 100 and the wiring board 200 by the heat conductive body 300 can be increased compared to the above-described total contact area of the first structural example.

The heat conductive body 300 has a higher thermal conductivity than the thermal conductivity of the air layer. By filling the air layer between the semiconductor package 100 and the wiring board 200 with the heat conductive body 300, heat can be easily dissipated from the semiconductor package 100 to the wiring board 200.

Next, a description will be given of a manufacturing method example of the second structural example of the memory system 1. In the manufacturing method example of the second structural example, the semiconductor package 100, the wiring board 200, and the heat conductive body 300 are prepared in the same manner as in the manufacturing method example of the first structural example. Next, the semiconductor package 100 and the wiring board 200 are stacked to form a stacked body 1a with the heat conductive body 300 sandwiched therebetween. Next, the stacked body 1a is heated to reflow the solder balls 401, and the semiconductor package 100 and the wiring board 200 are bonded by melting the solder balls 401. Thereafter, the heat conductive body 300 is fixed to the wiring board 200 using the screw 500. Openings for the screws 500 may be formed in the heat conductive body 300 and the wiring board 200 before fixing the heat conductive body 300. The memory system 1 can be manufactured by the above steps.

As described above, in the second structural example of the memory system 1, similar to the first structural example, by providing the heat conductive body 300 between the semiconductor package 100 and the wiring board 200, the heat dissipation area can be increased compared to the total area of the plurality of solder balls 401 in the X-Y plane. Therefore, the heat dissipation of the memory system 1 can be improved.

Further, in the second structural example, the screw 500 penetrates the heat conductive body 300 and the wiring board 200, so that heat can be easily dissipated from the heat conductive body 300 to the wiring board 200. Therefore, the heat dissipation of the memory system 1 can be further improved.

### Third Structural Example of Memory System 1

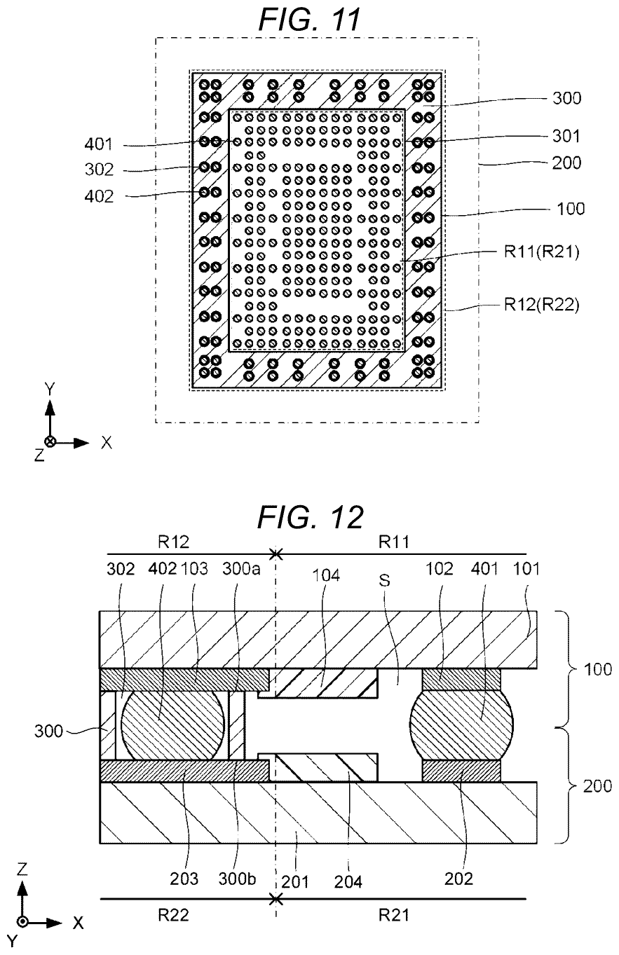

The structural example of the memory system 1 is not limited to the first structural example and the second structural example. FIGS. 10, 11, and 12 are schematic diagrams showing a third structural example of the memory system 1. FIG. 10 shows a part of the X-Z cross section of the memory system 1. FIG. 11 shows a part of the X-Y plane of the memory system 1. FIG. 12 is an enlarged diagram of a part of the X-Z cross section shown in FIG. 10.

The third structural example is different from the first structural example in that the heat conductive body 300 has an opening 302 and the solder balls 402 are disposed inside the opening 302. As a result, the third structural example is different from the first structural example in that the conductive pad 103 and the conductive pad 203 are connected. Hereinafter, portions of the third structural example different from the first structural example will be described. For the same portions as in the first structural example, the description of the first structural example can be appropriately incorporated.

The heat conductive body 300 further has an opening 302. The opening 302 overlaps with the region R22 in the X-Y plane and penetrates the heat conductive body 300 in the Z-axis direction. The heat conductive body 300 has a plurality of openings 302. The plurality of openings 302 are provided in a portion that does not overlap with the semiconductor package 100 in the Z-axis direction along the outer periphery of the opening 301 of the heat conductive body 300 in the X-Y plane. The number of openings 302 is not limited to the number shown in FIG. 11.

The memory system 1 further has a solder ball 402 that connects the conductive pad 103 and the conductive pad 203. The solder ball 402 is, for example, provided on the surface of the conductive pad 103. As shown in FIG. 12, the solder ball 402 is provided inside the opening 302 and are in contact with each of the conductive pad 103 and the conductive pad 203. The solder ball 402 may have a circular shape, for example, in the X-Y plane. The maximum thickness of the solder ball 402 in the Z-axis direction is, for example, 100 μm or more and 200 μm or less. The maximum width of the solder ball 402 in the X-axis direction or the Y-axis direction is 300 μm or more and 450 μm or less. The memory system 1 has a plurality of solder balls 402. As the solder ball 402, for example, a tin-silver-based lead-free solder or a tin-silver-copper-based lead-free solder can be used, and the solder ball 402 can be formed in the same step as the solder ball 401.

In the X-Y plane, the diameter of the opening 302 is preferably larger than the diameter of the solder ball 402. Accordingly, the solder ball 402 can be separated from the inner wall surface of the opening 302. And a short circuit between the solder ball 402 and the heat conductive body 300 can be prevented.

The heat conductive body 300 is fixed in contact with the region R12 by the solder balls 402 between the semiconductor package 100 and the wiring board 200. The heat conductive body 300 does not overlap with the region R11 when viewed in the thickness direction (Z-axis direction) of the wiring board 200.

As described above, in the third structural example, it is possible to increase the contact area between the semiconductor package 100 and the wiring board 200 by the heat conductive body 300 in the X-Y plane. Therefore, by filling the air layer between the semiconductor package 100 and the wiring board 200 with the heat conductive body 300, heat can be easily dissipated from the semiconductor package 100 to the wiring board 200. In addition, by providing the solder ball 402, it is possible to stably fix the heat conductive body 300 compared to the first structural example. Next, a manufacturing method example of the third structural example of the memory system 1 will be described. In the third structural example, the semiconductor package 100, the wiring board 200, and the heat conductive body 300 are prepared in the same manner as in the manufacturing method example of the first structural example. Next, the semiconductor package 100 and the wiring board 200 are stacked to form a stacked body 1a with the heat conductive body 300 sandwiched therebetween. Next, the stacked body 1a is heated to reflow the solder balls 401 and the solder balls 402, and the semiconductor package 100 and the wiring board 200 are bonded by melting the solder balls 401 and the solder balls 402. The memory system 1 can be manufactured by the above steps.

As described above, in the third structural example, similar to the first structural example, by providing the heat conductive body 300 between the semiconductor package 100 and the wiring board 200, the heat dissipation area can be increased compared to the total area of the plurality of solder balls 401 in the X-Y plane. Therefore, the heat dissipation of the memory system 1 can be improved.

Furthermore, in the third structural example, the semiconductor package 100 and the wiring board 200 are bonded by the solder ball 402 in addition to the solder ball 401. As a result, the deviation of the heat conductive body 300 can be prevented.

The third structural example can be appropriately combined with the first structural example and the second structural example. For example, in the X-Y plane, the heat conductive body 300 may extend to protrude from the semiconductor package 100, and the heat conductive body 300 may be fixed to the wiring board 200 by the screw 500. Since the screw 500 penetrates the heat conductive body 300 and the wiring board 200, heat can be easily dissipated from the heat conductive body 300 to the wiring board 200. Therefore, the heat dissipation of the memory system 1 can be further improved.

### Configuration Example of Semiconductor Module Having Memory System

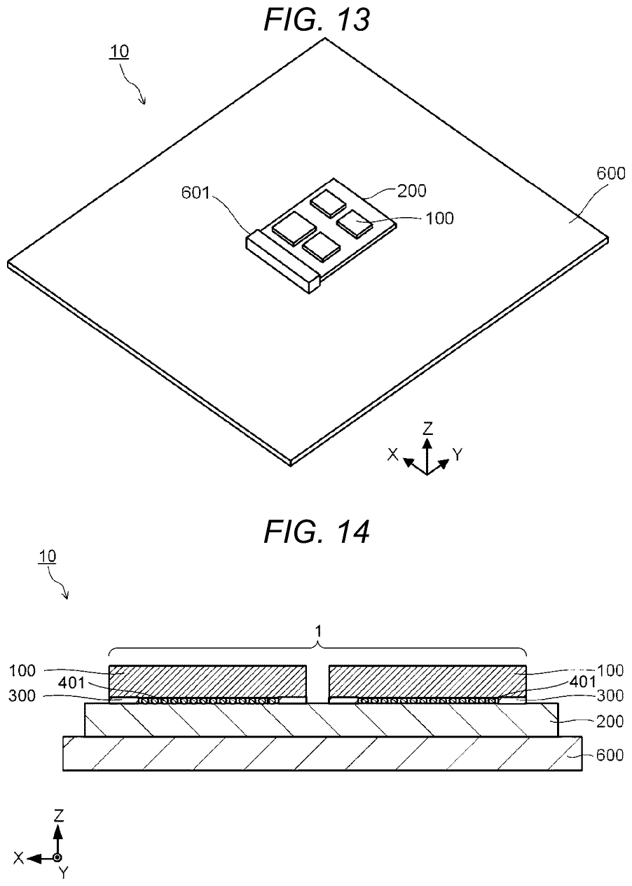

Next, a configuration example of a semiconductor module having a memory system 1, which is an example of a semiconductor device, will be described. FIGS. 13 and 14 are schematic diagrams showing a configuration example of a semiconductor module 10 having the memory system 1. FIG. 13 shows a perspective diagram of the semiconductor module 10. FIG. 14 shows an enlarged diagram of a part of the X-Z cross section of the semiconductor module 10.

The semiconductor module 10 has a memory system 1 having a semiconductor package 100, a wiring board 200, and a heat conductive body 300, and a circuit board 600. FIG. 13 shows an example of a semiconductor module 10 having a multi-chip structure.

The semiconductor module 10 includes a plurality of semiconductor packages 100. The plurality of semiconductor packages 100 are provided on the wiring board 200 with a plurality of heat conductive bodies 300 sandwiched therebetween. Each of the plurality of semiconductor packages 100 has a memory controller 11, a NAND memory 12, and a DRAM 13 shown in FIG. 1. Although FIG. 14 shows the heat conductive body 300 of the first structural example of the memory system 1 as an example, the present invention is not limited thereto, and any of the heat conductive body 300 of the second structural example and the third structural example of the memory system 1 may be applied to the semiconductor module 10.

The wiring board 200 is provided on the circuit board 600 and is electrically connected to the circuit board 600 from the connection terminal in a connection portion 601 provided on the circuit board 600. An example of the circuit board 600 includes a motherboard or the like. The circuit board 600 may have an arithmetic device such as a central processing unit (CPU).

Other descriptions of the semiconductor package 100, the wiring board 200, and the heat conductive body 300 can be appropriately referred to the descriptions of the semiconductor package 100, the wiring board 200, and the heat conductive body 300 in the first to third structural examples of the memory system 1.

In the semiconductor module having the memory system, by applying any of the first to third structural examples of the memory system 1 and having the heat conductive body 300 between the semiconductor package 100 and the wiring board 200, the heat dissipation area can be increased compared to the total area of the plurality of solder balls 401 in the X-Y plane. Therefore, the heat dissipation of the semiconductor module can be improved.

### Configuration Example of Semiconductor Module Mounted on Vehicle

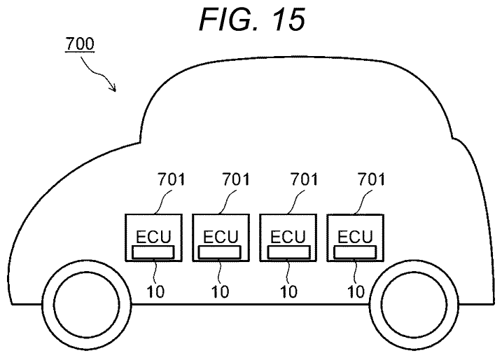

Next, a configuration example of a semiconductor module mounted on a vehicle will be described. FIG. 15 is a schematic diagram showing a configuration example of a vehicle having the semiconductor module 10. FIG. 15 shows an example of a vehicle such as a hybrid vehicle or an electric vehicle.

An automobile 700 includes an electronic control unit (ECU) 701. The ECU 701 can electronically control each function of the automobile 700. The ECU 701 uses a Single Root I/O Virtualization (SR-IOV) function, which is, for example, an extension function of PCI Express (PCIe: registered trademark). The ECU 701 includes the semiconductor module 10.

The automobile 700 includes a plurality of ECUs 701. The plurality of ECUs 701 include, for example, an ECU that controls an engine, an ECU that controls a vehicle body, an ECU that controls an advanced driving assistance system, an ECU that controls a powertrain, an ECU that controls an in-vehicle infotainment (IVI) or a driver's seat, and the like. It is preferable that the plurality of ECUs 701 are provided, for example, at the lower portion of the seat of the automobile 700.

The semiconductor module 10 provided in the automobile 700 is, for example, likely to be exposed to a high-temperature environment due to an: increase in the temperature. Therefore, it is preferable to improve the heat dissipation of the semiconductor package 100 so that the thermal throttling of the ECU 701 does not operate as much as possible. Therefore, by using the semiconductor module 10 having any of the memory systems 1 according to the first to third structural examples as the storage of the ECU 701, for example, the heat dissipation of the ECU 701 can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a semiconductor package including a first surface with a first region and a second region around the first region, wherein the first region includes a first solder ball; and
a heat conductive body in contact with the second region, wherein the heat conductive body includes graphite and has a thermal conductivity equal to or higher than 400 W/m·K in a use temperature range.

2. The semiconductor device according to claim 1,
wherein the heat conductive body has an electrical resistivity equal to or lower than 1×10−6 S/m in the use temperature range.

3. The semiconductor device according to claim 1,
wherein the heat conductive body has a thickness equal to or greater 70 μm and equal to or less than 100 μm.

4. The semiconductor device according to claim 1,
wherein the heat conductive body has a first opening overlapped with the first region, and
the first solder ball is disposed inside the first opening.

5. The semiconductor device according to claim 1,
wherein the heat conductive body has a second opening overlapped with the second region, and
the second region includes a second solder ball disposed inside the second opening.

6. The semiconductor device according to claim 5,
wherein a diameter of the second opening is larger than a diameter of the second solder ball.

7. The semiconductor device according to claim 5,
wherein the second solder ball is separated from an inner wall surface of the second opening.

8. The semiconductor device according to claim 1, further comprising a substrate having a second surface,
wherein the heat conductive body is provided between the second region and the second surface, and is in contact with each of the second region and the second surface.

9. A vehicle electrical control unit comprising the semiconductor device according to claim 1.

10. The semiconductor device according to claim 1,
wherein the first region has higher heat generation property than the second region.

11. The semiconductor device according to claim 3,
wherein the thickness of the heat conductive body is less than a diameter of the first solder ball.

12. A semiconductor device comprising:
a substrate;
a semiconductor package having a first region including a first solder ball and a communication line, and a second region provided around the first region and including a second solder ball; and
a heat conductive body in contact with the second region, with the second solder ball between the substrate and the semiconductor package and not overlapped with the first region.

13. A manufacturing method of a semiconductor device that bonds a semiconductor package and a substrate, the semiconductor package including a first surface with a first region and a second region around the first region, the first region including a first solder ball, and the substrate having a second surface, the manufacturing method comprising:
forming a stacked body by stacking the semiconductor package and the substrate with a heat conductive body sandwiched between the second region and the second surface; and
bonding the semiconductor package and the substrate with the first solder ball by heating the stacked body to process the first solder ball,
wherein the heat conductive body includes graphite, and has a thermal conductivity equal to or greater than 400 W/m·K in a use temperature range.

14. The method according to claim 13, wherein the heat conductive body has an electrical resistivity equal to or lower than 1×10−6 S/m in the use temperature range.

15. The method according to claim 13, wherein the heat conductive body has a thickness equal to or greater 70 μm and equal to or less than 100 μm.

16. The method according to claim 13, further comprising:
forming a first opening in the heat conductive body that is overlapped with the first region,
wherein the first solder ball is disposed inside the first opening.

17. The method according to claim 13, further comprising:
forming a second opening in the heat conductive body that is overlapped with the second region,
wherein the second region includes a second solder ball disposed inside the second opening.

18. The method according to claim 17, wherein a diameter of the second opening is larger than a diameter of the second solder ball.

19. The method according to claim 18, wherein the second solder ball is separated from an inner wall surface of the second opening.

20. The method according to claim 13, wherein the first region has higher heat generation property than the second region.
